(19) United States
(12) Patent Application Publication
(10) Pub. No.: US 2015/0073738 A1
(43) Pub. Date: Mar. 12, 2015

(54) DETERMINING PROCESS VARIATION USING DEVICE THRESHOLD SENSITIVITES

(71) Applicant: International Business Machines Corporation, Armonk, NY (US)

(72) Inventors: Nathan Buck, Underhill, VT (US); Eric A. Foreman, Fairfax, VT (US); Jeffrey G. Hemmett, St. George, VT (US); Amol A. Joshi, Essex Junction, VT (US); Dileep N. Netrabile, South Burlington, VT (US); Vladimir Zolotov, Putnam Valley, NY (US); Hemlata Gupta, Hopewell Junction, NY (US)

(73) Assignee: International Business Machines Corporation, Armonk, NY (US)

(21) Appl. No.: 14/021,284

(22) Filed: Sep. 9, 2013

(51) Int. Cl. G01R 31/28

(52) U.S. Cl. CPC G01R 31/2851
USPC 702/65

(57) ABSTRACT

Embodiments of the present invention relate to determining process variations using device threshold sensitivities. A computing device determines first and second threshold voltages for first and second transistors, respectively, wherein the first and second transistors are included in an integrated circuit and are n-channel and p-channel field effect transistors, respectively. The computing device also determines process parameters that are associated with the integrated circuit using a combination of determined first and second threshold voltages, wherein the process parameter reflects random sensitivities, timing delay differences, timing delay and slew rate changes, and/or variations between low, high, and regular threshold voltages which are associated with the first and second transistors.

### BACKGROUND

The present disclosure relates generally to the field of testing integrated circuits, and more particularly to determining process variations using device threshold sensitivities. Integrated circuit (hereinafter “IC”) design is often requires a balancing of speed, area, power, and runtime constraints. However, an IC must meet the timing constraints in order to operate at the intended clock rate, so timing is an important design constraint. High-performance ICs have traditionally been characterized by the clock frequency at which they operate. Gauging the ability of a circuit/IC to operate at the specified speed requires an ability to measure, during the design process, its delay at numerous steps. Timing analysis is a method used to analyze a circuit to determine if the timing constraints imposed by components or interfaces are met.

As the capability to integrate a greater number of transistors in a single die or IC increase, it is becoming more common that an application-specific IC (hereinafter “ASIC”) is required, at least for high-volume applications. The chances of being able to design competitive products using only off-the-shelf components are continually diminishing. Very often, the systems designer must design the ICs, as well as the systems.

High-performance integrated circuits have traditionally been characterized by the clock frequency at which they operate. Gauging the ability of a circuit to operate at the specified speed requires the ability to measure, during the design process, its delay at numerous steps. Moreover, delay calculation must be incorporated into the inner loop of timing optimizers at various phases of design, such as logic synthesis, layout (placement and routing), and in in-place optimizations performed late in the design cycle. Statistical static timing analysis (SSTA) analyzes circuit delays statistically by considering delay variations. Delay variations are due to various types of process variations, for example, threshold voltage variations in transistors, lithography pattern variations, and chip-to-chip variations.

### SUMMARY

Embodiments of the present invention relate to determining process variations using device threshold sensitivities. A computing device determines first and second threshold voltages for first and second transistors, respectively, wherein the first and second transistors are included in an integrated circuit and are n-channel and p-channel field effect transistors, respectively. The computing device also determines process parameters that are associated with the integrated circuit using a combination of determined first and second threshold voltages, wherein the process parameters reflects random sensitivities, timing delay differences, timing delay and slew rate changes, and/or variations between low, high, and regular threshold voltages which are associated with the first and second transistors.

### BRIEF DESCRIPTION OF THE SEVERAL VIEWS OF THE DRAWINGS

FIG. 1 is a block diagram illustrating an environment, in accordance with an embodiment of the present invention.

FIG. 2 is a flowchart depicting operational steps of a program function, in accordance with an embodiment of the present invention.

FIG. 3 depicts a block diagram of components of a computing device, in accordance with an embodiment of the present invention.

### DETAILED DESCRIPTION

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer-readable medium(s) having computer-readable program code/instructions embodied thereon.

For purposes herein, an “insulator” is a relative term that means a material or structure that allows substantially less (<95%) electrical current to flow than does a “conductor.” The dielectrics (insulators) mentioned herein can, for example, be grown from either a dry oxygen ambient or steam and then patterned. Alternatively, the dielectrics herein may be formed from any of the many candidate high dielectric constant (high-k) materials, including but not limited to silicon nitride, silicon oxynitride, a gate dielectric stack of SiO₂ and Si₃N₄, and metal oxides like tantalum oxide. The thickness of dielectrics herein may vary contingent upon the required device performance.

Any combination of computer-readable media may be utilized. Computer-readable media may be a computer-readable signal medium or a computer-readable storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of a computer-readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer-readable storage medium may be any tangible medium that can contain, or store a program for use by or in connection with an instruction execution system, apparatus, or device.

A computer-readable signal medium may include a propagated data signal with computer-readable program code embodied therein, for example, in baseband or as part of a carrier wave. Such a propagated signal may take any of a variety of forms, including, but not limited to, electro-magnetic, optical, or any suitable combination thereof. A computer-readable signal medium may be any computer-readable medium that is not a computer-readable storage medium and that can communicate, propagate, or transport a program for use by or in connection with an instruction execution system, apparatus, or device.

Program code embodied on a computer-readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on a user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer-readable medium that can direct a computer, other programmable data processing apparatus, or other devices to function in a particular manner, such that the instructions stored in the computer-readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer-implemented process such that the instructions which execute on the computer or other programmable apparatus provide processes for implementing the functions/acts specified in the flowchart and/or block diagram block or blocks.

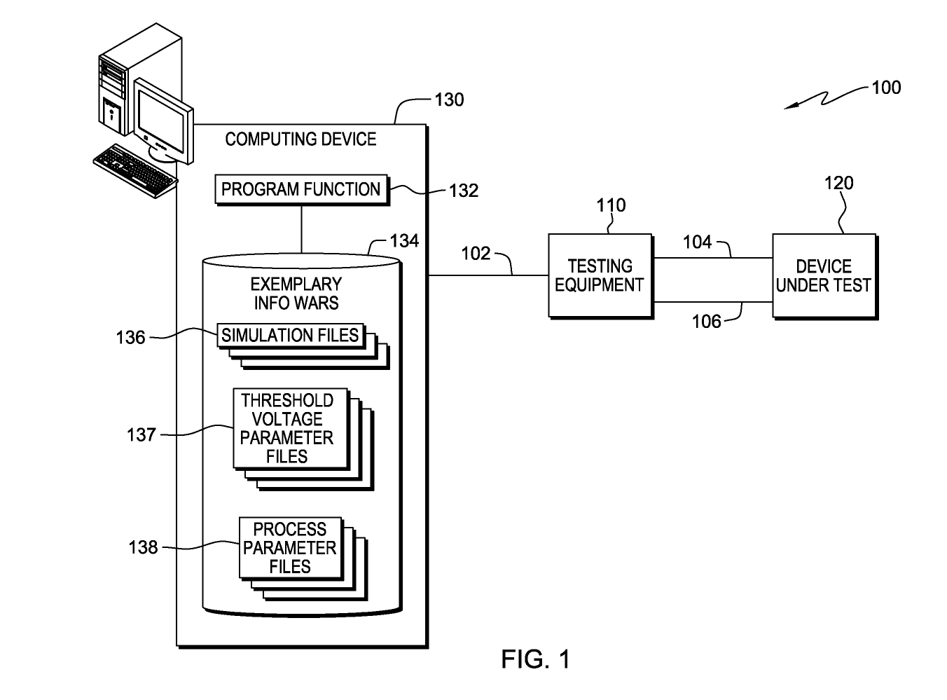

Embodiments of the present invention will now be described in detail with reference to the Figures. FIG. 1 is a block diagram illustrating an environment, generally designated 100, in accordance with one embodiment of the present invention.

Environment 100 includes testing equipment 110, device under test (hereinafter “DUT”) 120 and computing device 130. In another embodiment, testing equipment 110, DUT 120, computing device 130, or any combination thereof may be depicted as a single entity. Although not shown, environment 100 may include additional connections than those shown in FIG. 1. Although not shown, environment 100 may include additional connections than those shown in FIG. 1.

Computing device 130 may be a laptop computer, tablet computer, netbook computer, personal computer (PC), a desktop computer, a personal digital assistant (PDA), a smart phone, or any programmable electronic device capable of communicating with testing equipment 100. In accordance with an embodiment of the present invention, DUT 120 is associated with testing equipment 110 via test input line 104 and test output line 106, in accordance with an embodiment of the invention. DUT 120 can be a semiconductor device, for example, a die on a wafer or the resulting packaged part, transistor, solar cell, digital or analog integrated circuit, or a type of diode, for example, a light emitting diode, silicon rectifier, or photodiode. For example, DUT 120 may be a semiconductor device coming off an assembly line that is to be given a final in-line test. In general, DUT 120 may be any device manufactured utilizing a semiconductor material, for example, silicon dioxide.

Testing equipment 110 may be associated with computing device 130, via communications link 102, and DUT 120, via test input line 104 and test output line 106, in accordance with an embodiment of the invention. Typically, testing equipment 110 is any testing equipment that can apply voltage to a semiconductor device, for example, DUT 120, by test input line 104, measure current and voltage readings of DUT 120 by test output line 106, and transmit voltage measurements or readings to a computing device, for example, computing device 110, via communications line 102. In another embodiment, testing equipment 110 may store the voltage measurement data locally or externally via a networked computing device or storage device. In general, testing equipment 110 may be any testing equipment capable of applying voltage pulses to a semiconductor device, for example, DUT 120, measuring voltage, and produce voltage measurement data, in accordance with an embodiment of the present invention.

Computing device 130 is in communication with testing equipment 110 via communications line 102, in accordance with an embodiment of the present invention. Computing device 130 is a computing device that determines process parameters. A process parameter is a measurement of the current status of a process under control, for example, the temperature of a furnace. Computing device 130 includes exemplary information store 134 and program function 132. Exemplary information store 134 is an information repository that includes simulation files 136, threshold voltage parameter files 137, and process parameter files 138.

Simulation files 136 are included in exemplary information store 134, in accordance with an embodiment of the present invention. Simulation files 136 are files that include the results of computer simulations of circuits and/or integrated circuits, wherein the simulation is obtained in very small time steps and the current-voltage characteristics of each device are modeled. Current-voltage characteristics of a device describe the dependence of a terminal current on more than one terminal voltage difference. In an embodiment, simulation files 136 include the results of a Simulation Program with Integrated Circuit Emphasis-like (hereinafter “SPICE-like”) analysis, such as corner offsets.

SPICE is an electronic circuit simulator used to analyze the integrity of circuit design and to predict circuit behavior by actually replicating the behavior of an actual circuit. Further, the high costs of IC manufacturing make it essential to design the circuit to be as close to ideal as possible before the IC is first built. SPICE-like corner offsets describe extreme fabrication parameters variations within which a circuit that has been etched onto a wafer must function as designed. SPICE-like corner offsets include slow-fast offsets (hereinafter “sf”), which correspond to a slow Nfet, fast Pfet combination, and fast-slow offsets (hereinafter “fs”), which correspond to fast Nfet, slow Pfet offsets.

Simulation files 136 include SPICE-like simulation results. SPICE-like simulation results include transient analysis plots and DC transfer curve plots. SPICE-like analyses are executed using pre-determined SPICE-like diode model parameters, such as parameters that describe transport saturation current, series resistance, capacitance at a particular bias, diode grading coefficient exponent, and built-in diode contact potential. SPICE-like analyses are executed using pre-determined SPICE-like transistor parameters, such as parameters that describe transistor threshold voltage, carrier mobility in bulk, thickness of gate oxide, lateral diffusion of junction under gate, and/or body-effect.

Voltage threshold parameter files 137 include threshold voltage information, for example, threshold voltage information on n-channel and p-channel field effect transistors (hereinafter “nFET” and “pFET” respectively). A field-effect transistor is a transistor that uses an electronic field to control the shape and hence the conductivity of a channel of one type of charge carrier in a semiconducting material. The threshold voltage of a field effect transistor the value of the gate-source voltage when the conducting channel just begins to connect the source and drain contacts of the transistor, allowing significant current to flow. Process parameter files 138 are included in exemplary information store 134, in accordance with an embodiment of the present invention. Process parameter files 138 include threshold voltage sensitivity parameter, random sensitivity parameter, off-track sensitivity parameter, reliability aging parameter, and threshold voltage variation parameter information generated by program function 132. Sensitivity is a statistical measure of the portion of actual positives which are correctly identified as such.

The random sensitivity parameter describes the random sensitivity of switching Nfets and Pfets in a particular timing arc. The off-track sensitivity parameter describes nFET and pFET timing differences. The aging parameter describes the delay and slew change after a particular length of time, in hours, that an electrical current is applied to a device, such as DUT 120.

In accordance with an embodiment of the present invention, program function 132 is included in computing device 130. Program function 132 is software that determines process parameters associated with a circuit. A process parameter reflects the current state of a process under control, for example, the n-channel threshold voltage for a particular timing arc delay in DUT 120. As the performance characteristics of a process improve the value of the determined process parameter decreases, in accordance with an embodiment of the present invention. In an embodiment, program function 132 performs circuit simulations, for example, SPICE circuit simulation. In an embodiment, program function 132 generates simulation files 136 in response to simulating a circuit. Program function 132 generates threshold voltage parameter files 137 in response to testing equipment 110 applying voltage to DUT 120 via test input file 104 and transmitting the test output from test output line 106 via communications line 102. Program function 132 also generates process parameter files 138.

Program function 132 determines process parameters for devices, such as device of test 120. Process parameters described below use the canonical form reflected in equation [1].

xA*Nvt+xB*Pvt [1]

wherein xA and xB are predefined real numbers, and wherein Nvt and Pvt are determined threshold voltages of n-channel and p-channel field effect transistors (hereinafter “nFET” and “pFET” respectively), respectively. Characterizing process parameters using the form included in equation [1] reduces the amount of characterization required and takes advantage of the accuracy margin of second order parameters. In another embodiment, program function 120 determines Nvt and Pvt for every timing arc of delay and/or slew and for all input slew and/or load point in the device, for example, DUT 120 are defined. For example, Nvt and Pvt for a timing arc of delay associated with DUT 120 are 0.7 and 0.8 volts, respectively. Nvt and Pvt are discussed further below in reference to equations [2] through [6].

In another embodiment, program function 120 determines uncorrelated random sensitivity process parameters using equation [2].

$$\sqrt{\frac{cn}{nN} {Nvt}^{2} + \frac{cp}{nP} {Pvt}^{2}} \qquad [ 2 ]$$

wherein nN, and nP are quantities of switching n-channel and p-channel field effect transistors in communication with the integrated circuit, respectively, and wherein cn and cp are slow-fast and fast-slow SPICE-like corner offsets. For example, nN, and nP, 50 and 100, respectively, represent the quantities of switching n-channel and p-channel field effect transistors in communication with DUT 120, and cn and cp corner offsets for DUT 120 are 0.4 and 0.5, respectively. In yet another embodiment, cn and cp of equation [2] are computed as multipliers of an intrinsic or base delay of a performance monitor, such as a performance screen ring oscillator (hereinafter “PSRO”) circuit, that is in communication with a device under test, such as DUT 120. For example, applying the above noted Nvt, Pvt, nN, nP, cn, and cp to equation [2] yields 1.0691, which is the amount of uncorrelated random sensitivity in the timing arc.

In yet still another embodiment, program function 132 determine process parameters that define the timing delay difference of n-channel and p-channel field effect transistors in communication with the integrated circuit, such as the process parameters included in process parameter files 138, using equation [3].

x(−cn*Nvt+cp*Pvt) [3]

wherein x is a predefined real number, cn and cp are slow-fast and fast-slow SPICE-like corner offsets, and wherein Nvt and Pvt are the determined threshold voltages for a n-channel and p-channel field effect transistor, respectively. In an embodiment, x is based upon transistor modeling, circuit design, technology process information, and/or a predetermined amount of variability a user may desires to inject. In another embodiment, x is the difference in the off-track between the nFET and pFET SPICE models for the above noted nFET and pFET. For example, to determine the timing delay difference of the above noted nFET and pFET that are in communication with DUT 120, wherein x is 5, apply the above referenced cn, cp, Nvt, and Pvt to equation [3] yields 0.60, which is the amount of nFET and pFET off-track sensitivity. In yet another embodiment, cn and cp of equation [3] are computed as multipliers of an intrinsic or base delay of a performance monitor, such as a performance screen ring oscillator circuit, that is in communication with a device under test, such as DUT 120.

In yet another embodiment, program function 132 determines process parameters that define the timing delay and slew difference change after a predetermined power on hours of the integrated circuit is determined using equation [4].

x(R1+R2*Nvt+R3*Pvt) [4]

wherein x is a predefined real number, wherein Nvt and Pvt are the determined threshold voltages for a n-channel and p-channel field effect transistor, respectively, and wherein R1, R2, and R3 are a reliability temperature, voltage, and length of time, in hours, that an electrical current is applied to the gate (hereinafter “power-on hours”). For example, to define a timing delay and slew difference change associated with DUT 120 after a power-on hours of 10, wherein R1, R2, and R3 are 5, 5, and 10, respectively, apply the above defined x, R1, R2, R3, Nvt, and Pvt to equation [4], which yields 82.5.

In yet another embodiment, program function 132 determines process parameters that define the timing delay difference of the n-channel field effect transistor and p-channel field effect transistors in communication with DUT 120 using equations [5] and [6].

Lvt=Rvt+Rvt(Ln*Nvt+Lp*Pvt) [5]

Hvt=Rvt+Rvt(Hn*Nvt+Hp*Pvt) [6]

wherein Rvt is a regular threshold voltage, wherein Nvt and Pvt are the determined threshold voltages for a n-channel and p-channel field effect transistor, respectively, and Ln, Lp, Hn, and Hp are global parameters precomputed using a SPICE-like comparisons of a group of used cells that have a low, regular, and high threshold voltage, respectively. In an embodiment, equations [5] and [6] describe how voltage threshold varies from one voltage threshold type to another.

For example, to determine the delay and slew for Lvt associated with DUT 120 and Ln, Lp, Hn, Hp, and Rvt are 1.0, 1.0, 2.0, and 0.9, respectively, apply the above referenced Rvt, Nvt, Pvt, Ln and Lp to equation [5], which yields a value of 1.404. For example, to determine the delay and slew for Hvt associated with DUT 120, apply the above referenced Rvt, Nvt, Pvt, Hn, and Hp to equation [6], which yields 4.2. As stated above, smaller valued process parameters that are determined utilizing the above referenced equations are reflective of an improved performance compared to a similarly determined process parameter having a larger valued sensitivity, in accordance with an embodiment of the present invention. For example, if the uncorrelated random sensitivity process parameter, as determined by equation [2], for a first timing arc delay is lower than that of a second timing arc delay, then the first timing arc delay is preferred.

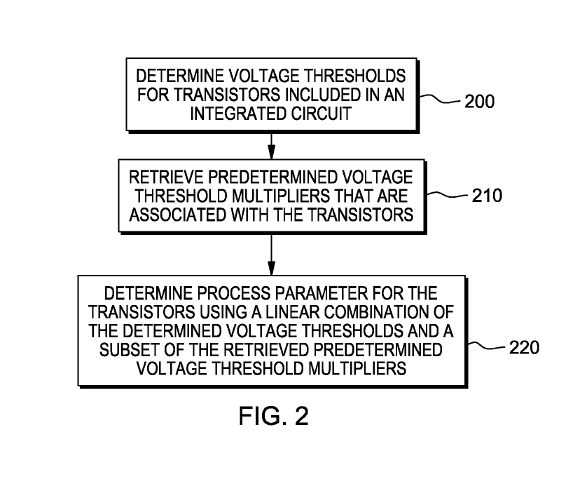

FIG. 2 is a flowchart depicting operational steps of program function 132, in accordance with an embodiment of the present invention.

Program function 132 determines threshold voltages for transistors included in an integrated circuit (step 200). For example, to determine threshold voltage for transistors program function 132 instructs testing equipment 110, via communications line 102, to apply a particular voltage for a particular amount of time to DUT 120, via test input line 104, and transmit the result to computing device 130, via communication line 102. In an embodiment, the threshold voltages are predetermined. Program function 132 receives the results and computes the threshold voltage using an industry standard threshold voltage calculation. Program function 132 retrieves predetermined threshold voltage multipliers (step 210). For example, program function 132 access simulation files 136 and retrieves the predetermined threshold voltage multipliers associated with the transistor.

Program function 132 determines a process parameter for the transistors using a linear combination of the determined threshold voltages and a subset of the retrieved predetermined threshold voltage multipliers (step 220). For example, program function 132 retrieves the appropriate threshold voltage multipliers from simulation files 136 that correspond to transistors that are included in threshold voltage parameter files 136 and combines them according to equation [2] to determine the random sensitivity parameter associated with transistors in communication with an integrated circuit.

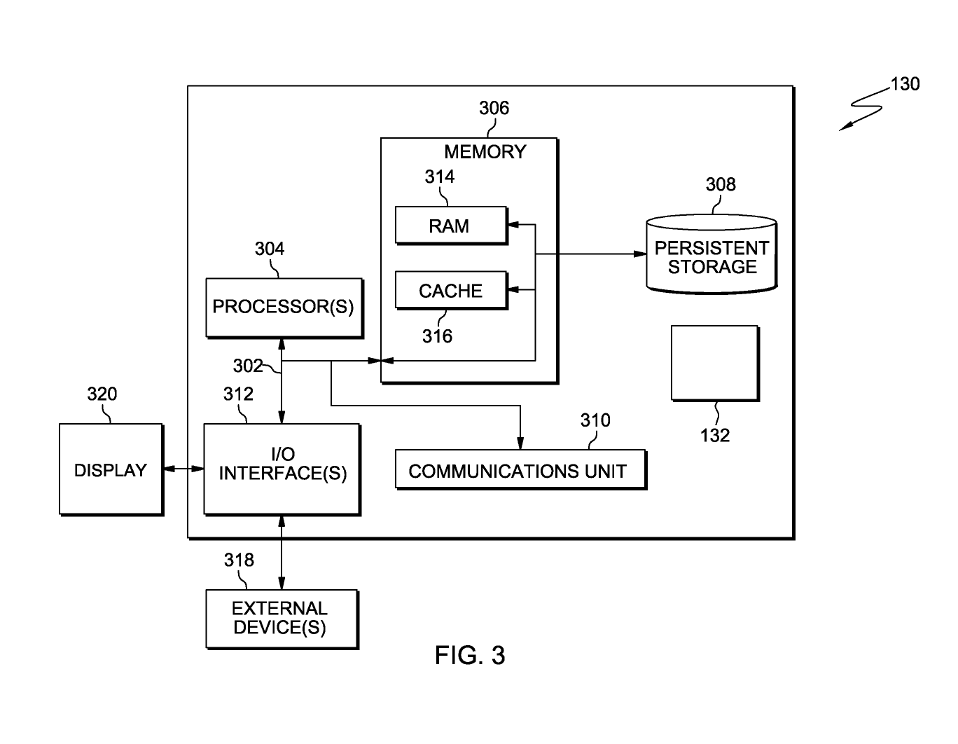

FIG. 3 depicts a block diagram of components of computing device 130, in accordance with an illustrative embodiment of the present invention. It should be appreciated that FIG. 3 provides only an illustration of one implementation and does not imply any limitations with regard to the environments in which different embodiments may be implemented. Many modifications to the depicted environment may be made.

Server computer 102 includes communications fabric 302, which provides communications between computer processor(s) 304, memory 306, persistent storage 308, communications unit 310, and input/output (I/O) interface(s) 312. Communications fabric 302 can be implemented with any architecture designed for passing data and/or control information between processors (such as microprocessors, communications

and network processors, etc.), system memory, peripheral devices, and any other hardware components within a system. For example, communications fabric 302 can be implemented with one or more buses.

Memory 306 and persistent storage 308 are computer-readable storage media. In this embodiment, memory 306 includes random access memory (RAM) 314 and cache memory 316. In general, memory 306 can include any suitable volatile or non-volatile computer-readable storage media.

Program function 132 is stored in persistent storage 308 for execution by one or more of the respective computer processors 304 via one or more memories of memory 306. In this embodiment, persistent storage 308 includes a magnetic hard disk drive. Alternatively, or in addition to a magnetic hard disk drive, persistent storage 308 can include a solid state hard drive, a semiconductor storage device, read-only memory (ROM), erasable programmable read-only memory (EPROM), flash memory, or any other computer-readable storage media that is capable of storing program instructions or digital information.

The media used by persistent storage 308 may also be removable. For example, a removable hard drive may be used for persistent storage 308. Other examples include optical and magnetic disks, thumb drives, and smart cards that are inserted into a drive for transfer onto another computer-readable storage medium that is also part of persistent storage 308.

Communications unit 310, in these examples, provides for communications with other data processing systems or devices. In these examples, communications unit 310 includes one or more network interface cards. Communications unit 310 may provide communications through the use of either or both physical and wireless communications links. Program function 132 may be downloaded to persistent storage 308 through communications unit 310.

I/O interface(s) 312 allows for input and output of data with other devices that may be connected to server computer 102. For example, I/O interface 312 may provide a connection to external devices 318 such as a keyboard, keypad, a touch screen, and/or some other suitable input device. External devices 318 can also include portable computer-readable storage media such as, for example, thumb drives, portable optical or magnetic disks, and memory cards. Software and data used to practice embodiments of the present invention, e.g., program function 132, can be stored on such portable computer-readable storage media and can be loaded onto persistent storage 308 via I/O interface(s) 312. I/O interface(s) 312 also connects to a display 320. Display 320 provides a mechanism to display data to a user and may be, for example, a computer monitor.

The programs described herein are identified based upon the application for which they are implemented in a specific embodiment of the invention. However, it should be appreciated that any particular program nomenclature herein is used merely for convenience, and thus the invention should not be limited to use solely in any specific application identified and/or implied by such nomenclature.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

What is claimed is:

1. A method comprising
determining, by a computing device, first and second threshold voltages for first and second transistors, respectively, wherein the first and second transistors are included in an integrated circuit and are n-channel and p-channel field effect transistors, respectively;
determining a process parameter associated with the integrated circuit using a combination of the determined first and second threshold voltages, wherein the process parameter reflects one or more of:
a random sensitivity associated with the first and second transistors;
a timing delay difference associated with the first and second transistors;
a timing delay and slew rate change associated with the first and second transistors after electric power has been applied to the integrated circuit for a predetermined amount of time; and
a variation between a low, high, and regular threshold voltage associated with the first and second transistors.

2. The method of claim 1, wherein the random sensitivity is determined using the following formula:
$$\sqrt{\frac{cn}{nN} {Nvt}^{2} + \frac{cp}{nP} {Pvt}^{2}}$$
wherein Nvt and Pvt are the determined the first and second threshold voltages, respectively;
wherein nN, and nP are quantities of switching n-channel and p-channel field effect transistors in communication with the integrated circuit, respectively;
wherein cn and cp are one or more of:
slow-fast and fast-slow simulation program with integrated circuit emphasis-like corner offsets that are associated with the integrated circuit, respectively; and
computed as multipliers of an intrinsic or base delay of a performance monitor and/or a performance screen ring oscillator circuit that is in communication with the integrated circuit.

3. The method of claim 1, wherein the timing delay difference of the first and second transistors is determined using the following formula:
x(−cn*Nvt+cp*Pvt)
wherein x is a predefined real number;
wherein Nvt and Pvt are the determined the first and second threshold voltages, respectively;
wherein cn and cp are one or more of:
slow-fast and fast-slow simulation program with integrated circuit emphasis-like corner offsets that are associated with the integrated circuit, respectively; and
computed as multipliers of an intrinsic or base delay of a performance monitor and/or a performance screen ring oscillator circuit that is in communication with the integrated circuit.

4. The method of claim 1, wherein the timing delay and slew rate change is determined using the following formula:
x(R1+R2*Nvt+R3*Pvt)
wherein x is a predefined real number;
wherein Nvt and Pvt are the determined first and second threshold voltages, respectively; and
wherein R1, R2, and R3 are a reliability temperature, voltage, and length of time, in hours, that an electrical current is applied to the transistor, respectively.

5. The method of claim 1, wherein the variation between the low, high, and regular threshold voltages of the transistor are determined using the following formula:
Lvt=Rvt+Rvt(Ln*Nvt+Lp*Pvt); and
Hvt=Rvt+Rvt(Hn*Nvt+Hp*Pvt)
wherein Rvt is a regular threshold voltage;
wherein Nvt and Pvt are the determined first and second threshold voltages, respectively; and
Ln, Lp, Hn, and Hp are global parameters computed using a simulation program with integrated circuit emphasis-like comparison of a group of transistors that have a low, regular, and high threshold voltage, respectively.

6. A computer program product, the computer program product comprising a computer readable storage medium having program code embodied therewith, the program code executable by a processor to:
determine, by a computing device that includes the processor, first and second threshold voltages for first and second transistors, respectively, wherein the first and second transistors are included in an integrated circuit and are n-channel and p-channel field effect transistors, respectively;
determine a process parameter associated with the integrated circuit using a combination of the determined threshold voltages, wherein the process parameter reflects one ore more of:
a random sensitivity associated with the first and second transistors;
a timing delay difference associated with the first and second transistors;
a timing delay and slew rate change associated with the first and second transistors after electric power has been applied to the integrated circuit for a predetermined amount of time; and
a variation between a low, high, and regular threshold voltage associated with the first and second transistors.

7. The computer program product of claim 6, wherein the random sensitivity is determined using program code that includes the following formula:
$$\sqrt{\frac{cn}{nN} {Nvt}^{2} + \frac{cp}{nP} {Pvt}^{2}}$$
wherein Nvt and Pvt are the determined the first and second threshold voltages, respectively;
wherein nN, and nP are quantities of switching n-channel and p-channel field effect transistors in communication with the integrated circuit, respectively;
wherein cn and cp are one or more of:
slow-fast and fast-slow simulation program with integrated circuit emphasis-like corner offsets that are associated with the integrated circuit, respectively; and
computed as multipliers of an intrinsic or base delay of a performance monitor and/or a performance screen ring oscillator circuit that is in communication with the integrated circuit.

8. The computer program product of claim 6, wherein the timing delay difference of the first and second transistors is determined using program code that includes the following formula:
x(−cn*Nvt+cp*Pvt)
wherein x is a predefined real number;
wherein Nvt and Pvt are the determined first and second threshold voltages, respectively;
wherein cn and cp are one or more of:
slow-fast and fast-slow simulation program with integrated circuit emphasis-like corner offsets that are associated with the integrated circuit, respectively; and
computed as multipliers of an intrinsic or base delay of a performance monitor and/or a performance screen ring oscillator circuit that is in communication with the integrated circuit.

9. The computer program product of claim 6, wherein the timing delay and slew rate change is determined using program code that includes the following formula:
x(R1+R2*Nvt+R3*Pvt)
wherein x is a predefined real number;
wherein Nvt and Pvt are the determined first and second threshold voltages, respectively; and
wherein R1, R2, and R3 are a reliability temperature, voltage, and length of time, in hours, that an electrical current is applied to the transistor, respectively.

10. The computer program product of claim 6, wherein the variation between the low, high, and regular threshold voltage of the transistor is determined using program code that includes the following formula:
Lvt=Rvt+Rvt(Ln*Nvt+Lp*Pvt); and
Hvt=Rvt+Rvt(Hn*Nvt+Hp*Pvt)
wherein Rvt is a regular threshold voltage;
wherein Nvt and Pvt are the determined first and second threshold voltages, respectively; and
Ln, Lp, Hn, and Hp are global parameters computed using a simulation program with integrated circuit emphasis-like comparison of a group of transistors that have a low, regular, and high threshold voltage, respectively.

11. A computer system comprising:
one or more computer processors;
one or more computer-readable storage media;
program instructions stored on the computer-readable storage media for execution by at least one of the one or more processors, the program instructions comprising:
program instructions to determine, by a computing device that includes the one or more processors, first and second threshold voltages for a first transistor and a second transistor, respectively, wherein the first and second transistors are included in an integrated circuit and are n-channel and p-channel field effect transistors, respectively;
program instructions to determine a process parameter associated with the integrated circuit using a combination of the determined threshold voltages, wherein the process parameter reflects one or more of:
a random sensitivity associated with the first and second transistors;
a timing delay difference associated with the first and second transistors;
a timing delay and slew rate change associated with the first and second transistors after electric power has been applied to the integrated circuit for a predetermined amount of time; and
a variation between a low, high, and regular threshold voltage associated with the first and second transistors.

12. The computer system of claim 11, wherein the random sensitivity is determined using program code that includes the following formula:
$$\sqrt{\frac{cn}{nN} {Nvt}^{2} + \frac{cp}{nP} {Pvt}^{2}}$$
wherein Nvt and Pvt are the determined the first and second threshold voltages, respectively;
wherein nN, and nP are quantities of switching n-channel and p-channel field effect transistors in communication with the integrated circuit, respectively;
wherein cn and cp are one or more of:
slow-fast and fast-slow simulation program with integrated circuit emphasis-like corner offsets that are associated with the integrated circuit, respectively; and
computed as multipliers of an intrinsic or base delay of a performance monitor and/or a performance screen ring oscillator circuit that is in communication with the integrated circuit.

13. The computer system of claim 11, wherein the timing delay difference of the first and second transistors is determined using program code that includes the following formula:
x(−cn*Nvt+cp*Pvt)
wherein x is a predefined integer;
wherein Nvt and Pvt are the determined first and second threshold voltages, respectively;
wherein cn and cp are one or more of:
slow-fast and fast-slow simulation program with integrated circuit emphasis-like corner offsets that are associated with the integrated circuit, respectively; and
computed as multipliers of an intrinsic or base delay of a performance monitor and/or a performance screen ring oscillator circuit that is in communication with the integrated circuit.

14. The computer system of claim 11, wherein the timing delay and slew rate change is determined using program code that includes the following formula:
x(R1+R2*Nvt+R3*Pvt)
wherein x is a predefined real number;
wherein Nvt and Pvt are the determined first and second threshold voltages, respectively; and
wherein R1, R2, and R3 are a reliability temperature, voltage, and length of time, in hours, that an electrical current is applied to the transistor, respectively.

15. The computer system of claim 11, wherein the variation between the low, high, and regular threshold voltage of the transistor is determined using program code that includes the following formula:
Lvt=Rvt+Rvt(Ln*Nvt+Lp*Pvt); and
Hvt=Rvt+Rvt(Hn*Nvt+Hp*Pvt)
wherein Rvt is a regular threshold voltage;
wherein Nvt and Pvt are the determined first and second threshold voltages, respectively; and
Ln, Lp, Hn, and Hp are global parameters computed using a simulation program with integrated circuit emphasis-like comparison of a group of transistors that have a low, regular, and high threshold voltage, respectively.
